(19) United States
(12) Patent Application Publication
(10) Pub. No.: US 2008/0203458 A1
(43) Pub. Date: Aug. 28, 2008

(54) Semiconductor Memory Device and Method of Fabricating the Same

(75) Inventor: Joo Won Hwang, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/959,523

(22) Filed: Dec. 19, 2007

(30) Foreign Application Priority Data
Feb. 22, 2007 (KR) 10-2007-0017913

(51) Int. Cl. H01L 29/78; H01L 21/762

(52) U.S. Cl. 257/314; 438/430; 257/E29.255; 257/E21.546

(57) ABSTRACT

This patent relates to a semiconductor memory device and a method of fabricating the same. The semiconductor memory device may include a semiconductor substrate in which a tunnel insulating layer, and a first conductive layer. At least a portion of the semiconductor substrate is removed to form a trench. A first insulating layer may be formed on an internal surface of the trench. A shield layer may be made of a conductive material is formed on the first insulating layer. A second insulating layer may be formed on the shield layer and is configured to gap fill the trench.

### CROSS-REFERENCES TO RELATED APPLICATIONS

This patent claims priority to Korean patent application number 10-2007-17913, filed on Feb. 22, 2007, the disclosure of which is incorporated by reference in its entirety.

### TECHNICAL FIELD

This patent relates to a semiconductor memory device and a method of fabricating the same and, more particularly, to a semiconductor memory device wherein a shield layer is formed between cells and a method of fabricating the same.

### BACKGROUND OF THE INVENTION

As semiconductor memory devices have become highly integrated, an increased interference is generated, for example, between word lines in NAND flash memory devices. This interference is generated more likely in a multi-level cell (MLC) in which a number of bits are stored in one cell than in a single level cell (SLC) in which one bit is stored in one cell.

Generally, a self-aligned method is used when fabricating a flash memory device having a narrow line width. This fabrication method is vulnerable to, in particular, interference which may be caused by the capacitance existing between cells. Interference may be overcome by securing a coupling characteristic including a process of controlling an Effective Field oxide Height (EFH) of an isolation layer by etching an isolation layer to a certain depth.

However, there are some limitations when controlling the EFH to a certain depth. A conventional semiconductor device includes a tunnel oxide layer and a conductive layer for a floating gate. The tunnel oxide layer and the conductive layer may be patterned and may be formed over a semiconductor substrate. A portion of the semiconductor substrate may be removed, thus forming a trench. The trench is gap filled with an insulating layer for an isolation layer. Some of the isolation layer may be etched for the EFH. However, the tunnel oxide layer may be exposed and damaged at the time of etching the isolation layer for lowering the EFH. Once the tunnel oxide layer is damaged, an operating capability of a device is significantly lowered and the device may malfunction.

### SUMMARY OF THE INVENTION

In an embodiment of the invention, an isolation layer is formed in a trench of an isolation region. An EFH is controlled so that the height of a central portion of the isolation layer is lowered than edge portions of the isolation layer. Thus, edge portions of a tunnel insulating layer formed in an active region can be prevented from being exposed while lowering the height of the central portion the isolation layer, and further the etch damage to the tunnel insulating layer can be prevented. A shield layer is formed between floating gates. Accordingly, an interference phenomenon between the floating gates can be prevented.

In an embodiment of the invention, a semiconductor memory device includes a semiconductor substrate in which a tunnel insulating layer, a first conductive layer, and a trench are formed. A first insulating layer is formed on an internal surface of the trench. A shield layer may be formed of a conductive material on the first insulating layer. A second insulating layer may be formed on the shield layer and gaps to fill the trench.

In an embodiment of the invention, the shield layer may be formed of a polysilicon layer. The second insulating layer may have a height lower than that of the first insulating layer. The first insulating layer may have a height higher than that of the tunnel insulating layer.

In an embodiment of the invention, there is provided a method of fabricating a semiconductor memory device. A semiconductor substrate in which a tunnel insulating layer pattern, a first conductive layer pattern, and a trench are formed. A first insulating layer and a shield layer are formed over a surface of the trench and may be sequentially formed. A second insulating layer is formed on the shield layer within the trench. A height of the first insulating layer and the second insulating layer are lowered.

In an embodiment of the invention, a step may be generated between the first insulating layer and the second insulating layer to lower the height of the first insulating layer and the second insulating layer. The step may cause the height of the second insulating layer to lower than the height of the first insulating layer.

In an embodiment of the invention, the first insulating layer and the second insulating layer may be formed of a material having the same etch rate. The first insulating layer and the second insulating layer may be formed of an oxide layer.

In an embodiment of the invention, the shield layer may be formed of a polysilicon layer and may be formed to a thickness, which is smaller than ½ of an upper width of the second insulating layer.

In another embodiment of the invention, a semiconductor memory device includes a semiconductor substrate in which a tunnel insulating layer, a first conductive layer, and a trench are formed. An insulating layer may be formed within the trench and a shield layer may be formed at a center of the insulating layer.

In an embodiment of the invention, the shield layer may be formed between the first conductive layers. The shield layer may be formed of a metal layer or a conductive layer.

In an embodiment, a dielectric layer and a second conductive layer are further sequentially laminated over the first conductive layer, the insulating layer, and the shield layer.

### BRIEF DESCRIPTION OF THE DRAWINGS

For a more complete understanding of the disclosure, reference should be made to the following detailed description and accompanying drawings wherein:

FIGS. 1A to 1H are sectional views illustrating a method of fabricating a semiconductor memory device according to an embodiment of the invention; and

FIG. 2 is a sectional view illustrating a method of fabricating a semiconductor memory device according to another embodiment of the invention.

### DESCRIPTION OF SPECIFIC EMBODIMENTS

While the patent is susceptible to various modifications and alternative forms, certain embodiments as shown by way of example in the drawings and these embodiments will be described in detail herein. It will be understood, however, that this disclosure is not intended to limit the patent to the particular forms described, but to the contrary, the patent is intended to cover all modifications, alternatives, and equivalents falling within the spirit and scope of the patent defined by the appended claims.

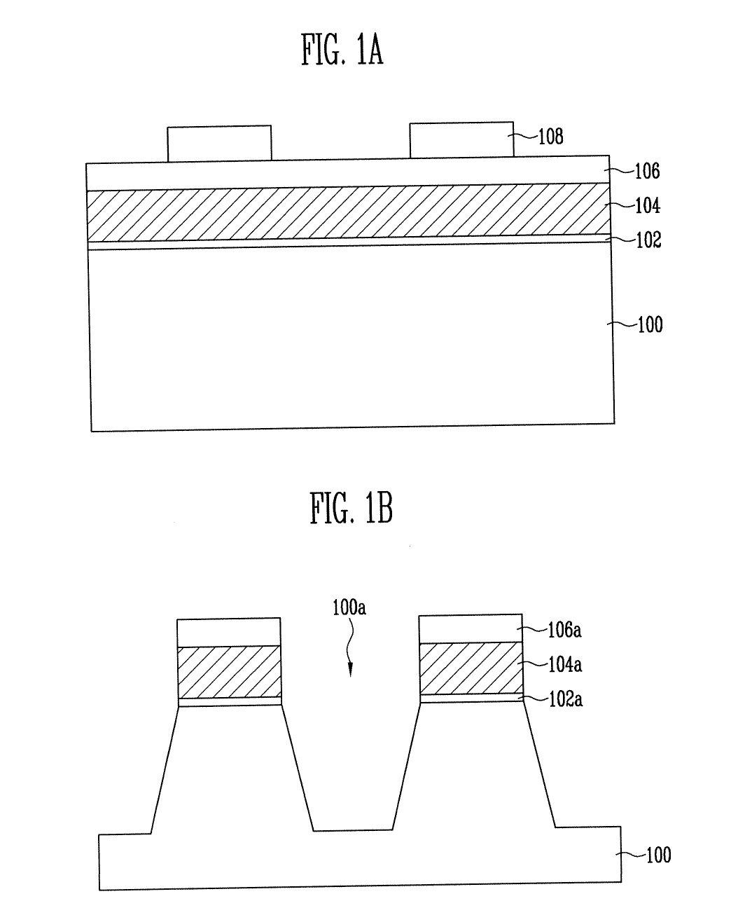

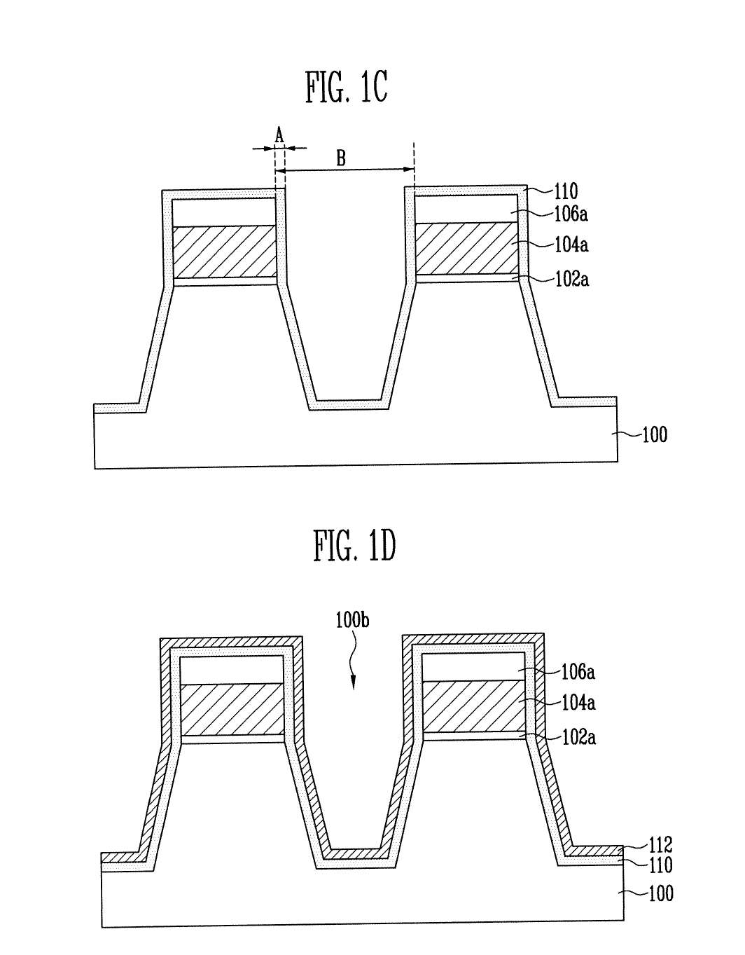

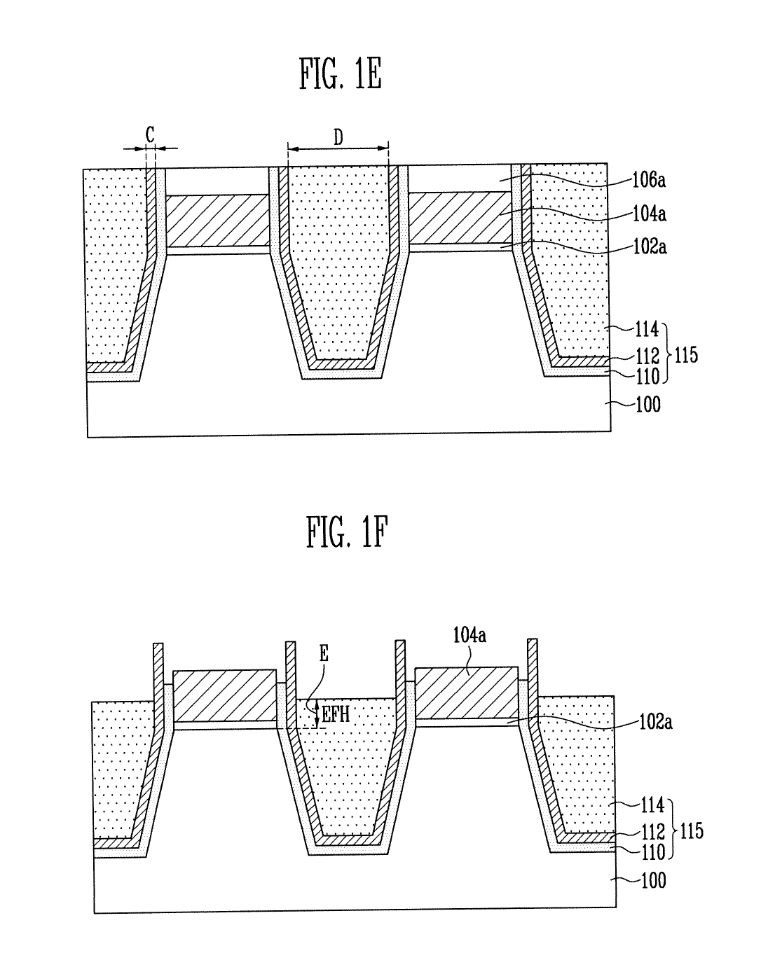

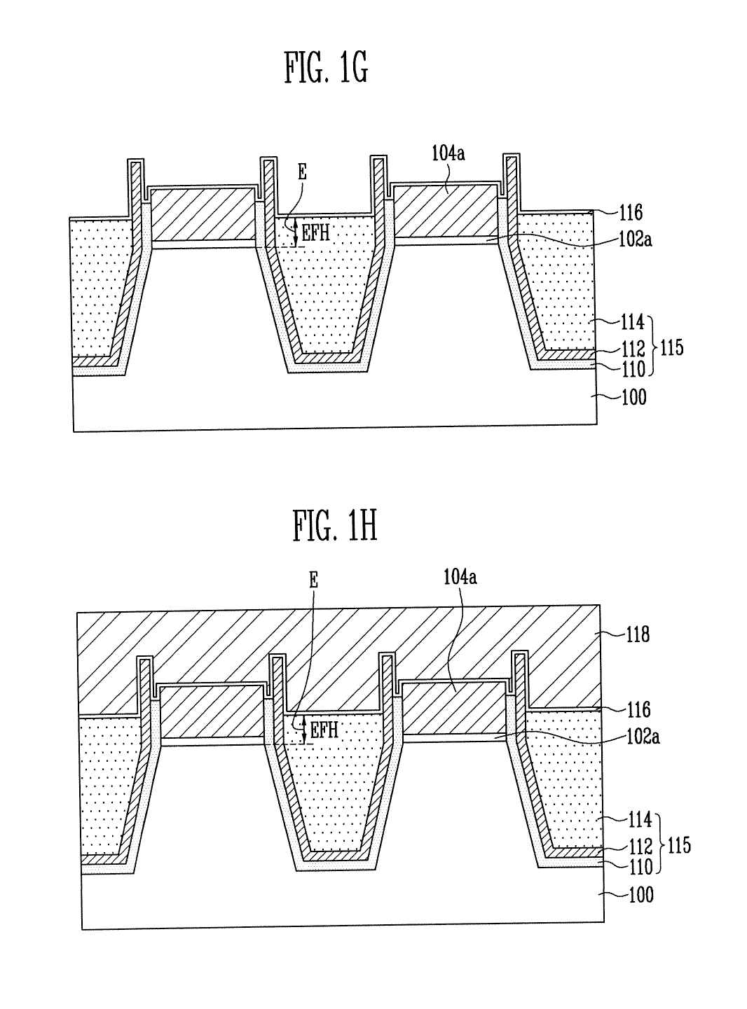

Referring to FIG. 1A, a tunnel insulating layer 102, a first conductive layer 104 for a floating gate, a first mask film 106, and a second mask film 108 are formed over a semiconductor substrate 100. The tunnel insulating layer 102 may be formed, for example, of an oxide layer and the first mask film 106 may be formed, for example, of a nitride layer. The second mask film 108 serves as a mask for patterning the floating gate 104 and an active region of the semiconductor substrate 100 in a self-aligned manner.

Referring to FIG. 1B, a first mask film pattern 106a, a first conductive layer pattern 104a, and a tunnel insulating layer pattern 102a are formed by performing an etching process on the second mask film 108 (as shown in FIG. 1A). At least a portion of the semiconductor substrate 100 is removed, thereby forming a trench 100a. The second mask film 108 is then removed.

Referring to FIG. 1C, a first insulating layer 110 for an isolation layer is formed over the entire surface of the semiconductor substrate 100 including the tunnel insulating layer pattern 102a, the first conductive layer pattern 104a, and the first mask film pattern 106a. The first insulating layer 110 may be formed, for example, of an oxide layer. The first insulating layer 110 may be formed to have a width narrower than a width B of an isolation region in consideration of a thickness of a shield layer 112 (as shown in FIG. 1D) formed on sidewalls of the first insulating layer 110. For example, the first insulating layer 110 may be formed to have a width, which is approximately ⅕ to ⅓ of a width D of a second insulating layer 114 (as shown FIG. 1E).

Referring to FIG. 1D, a shield layer 112 is formed on a surface of the first insulating layer 110. The shield layer 112 serves as an interface between the first insulating layer 110 and the second insulating layer 114 (as shown in FIG. 1E). The shield layer 112 may be formed, for example, of a metal layer or a conductive layer, preferably, a polysilicon layer. A thickness of the shield layer 112 formed on sidewall of the first insulating layer 110 may be smaller than half a width D of a region 100b in which the second insulating layer 114.

Referring to FIG. 1E, the second insulating layer 114 is formed on the shield layer 112 so that the region 100b is gap filled. The second insulating layer 114 may be formed, for example, of an oxide layer in the same manner as the first insulating layer 110. A chemical mechanical polishing (CMP) process may be performed in order to expose the first mask film pattern 106a. However, other techniques may be used. As shown in FIG. 1E, at least a portion of the first insulating layer 110 and the shield layer 112 on the active region are removed, leaving the first mask film pattern 106a exposed. Thus, the first insulating layer 110 and the shield layer 112 are isolated. Consequently, the first insulating layer 110, the shield layer 112, and the second insulating layer 114, defining an isolation layer 115, is formed within the region 100b.

Referring to FIG. 1F, the first mask film pattern 106a (as shown in FIG. 1E) is removed by any known technique in order to expose the first conductive layer pattern 104a. An optional conductive layer for a floating gate may be formed on the first conductive layer pattern 104a. A process of controlling the EFH may be performed by etching the isolation layer 115, for example, using an etching process in order to lower the height of the first and second insulating layers 110 and 114. The first insulating layer 110 and the second insulating layer 114 may be etched at the same time through a single etching process. Since an area of the exposed second insulating layer 114 is wider than an area of the exposed first insulating layer 110, the second insulating layer 114 is etched faster than the first insulating layer 110.

Due to the difference in the etch rate between the exposed first insulating layer 110 and the exposed second insulating layer 114, the etching process is performed in order to control a height (E) of the second insulating layer 114 to be identical to a desired EFH, the height of the first insulating layer 110 being brought in contact with a cell remains higher than the second insulating layer 114. Consequently, interference between cells can be reduced and the tunnel insulating layer pattern 102a is protected by the first insulating layer 110 during the etching process, thus preventing exposure of the tunnel insulating layer pattern 102a.

Referring to FIG. 1G, a dielectric layer 116 is formed over the entire surface of the isolation layer 115, including the conductive layer pattern 104a. The dielectric layer 116 may be formed to have a stack structure of an oxide layer-a nitride layer-an oxide layer. The present embodiment may also be applied to a silicon-oxide-nitride-oxide-silicon (SONOS) structure. In an embodiment, the dielectric layer may be formed of a high dielectric (high-k) layer.

Referring to FIG. 1H, a second conductive layer 118 for a control gate is formed on the dielectric layer 116. A gate formation process is then performed by any known technique.

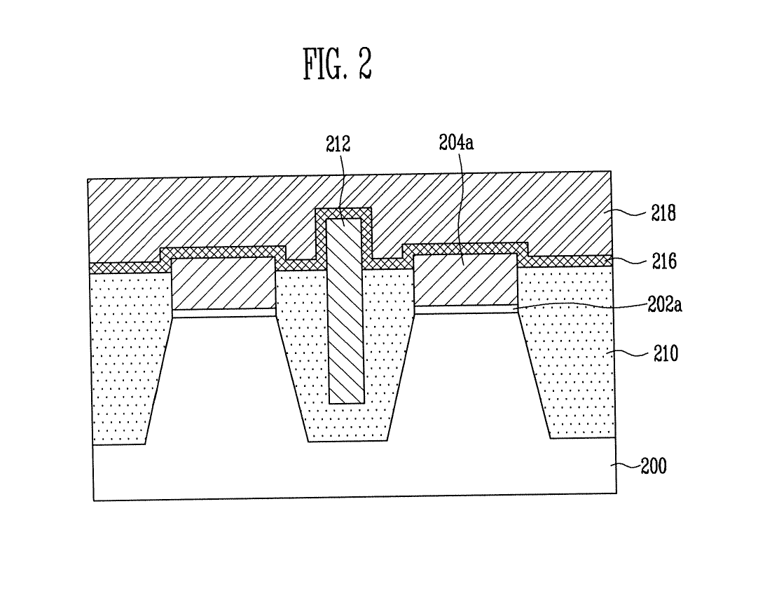

FIG. 2 is a sectional view illustrating a method of fabricating a semiconductor memory device according to another embodiment of the invention. The embodiment is similar to the embodiment illustrated in FIGS. 1A-1H, and like elements are referred to using like reference numerals wherein, for example, 100, 102a, 104a, 116 and 118 correspond to 200, 202a, 204a, 216 and 218, respectively. In the embodiment shown in FIG. 2, an insulating layer 210 may be gap filled within a trench for isolation and serves as an isolation layer. A central region of the isolation layer 210 may be etched in order to form a trench within the isolation layer 210. A shield layer 212 is formed, for example, at the center region of the isolation layer 210. As shown, the shield layer 212 may be projected upwardly as high as a mask pattern (not shown) in which the mask pattern is used to form the trench for isolation. The shield layer 212 may be formed, for example, of a polysilicon layer.

As described above, the shield layer 112 or 212 is formed between the floating gate 104a and the floating gate 204a, respectively. Accordingly, an interference phenomenon between adjacent elements is reduced and therefore, improving the reliability of a semiconductor device.

As described above, the isolation layer 210 is formed in the trench of the isolation region. The EFH is controlled so that the height of the central portion of the isolation layer 210 is lowered than the edge portions of the isolation layer 210. Thus, the edge portions of the tunnel insulating layer 202a formed in the active region can be prevented from being exposed while lowering the height of the isolation layer 210, for preventing etch damage to the tunnel insulating layer during the etching process. Further, the shield layer 212 is formed between the floating gates 204a. Accordingly, an interference phenomenon between the floating gates is prevented.

What is claimed is:

1. A semiconductor memory device comprising:
a semiconductor substrate in which a tunnel insulating layer, a first conductive layer, and a trench are formed;
a first insulating layer formed on an internal surface of the trench;
a shield layer formed on the first insulating layer and formed of a conductive material; and
a second insulating layer formed on the shield layer and filling the trench.

2. The semiconductor memory device of claim 1, wherein the shield layer is formed of a polysilicon layer.

3. The semiconductor memory device of claim 1, wherein the second insulating layer has a height lower than that of the first insulating layer.

4. The semiconductor memory device of claim 1, wherein the first insulating layer has a height higher than that of the tunnel insulating layer.

5. The semiconductor memory device of claim 1, wherein a width of the shield layer is smaller than ½ of the width of the second insulating layer.

6. The semiconductor memory device of claim 1, wherein a width of the first insulating layer is ⅕ to ⅓ of the width of the second insulating layer.

7. A method of fabricating a semiconductor memory device comprising:
providing a semiconductor substrate in which a tunnel insulating layer pattern, a conductive layer pattern, and a trench are formed;
forming a first insulating layer and a shield layer over an internal surface of the trench;
forming a second insulating layer on the shield layer to fill the trench; and
lowering a height of the first insulating layer and the second insulating layer.

8. The method of claim 7, wherein the step of lowering the height of the first insulating layer and the second insulating layer, the height of the first insulating layer is higher than that of the second insulating layer.

9. The method of claim 7, wherein a width of the first insulating layer is ⅕ to ⅓ of the width of the second insulating layer 10. The method of claim 7, wherein the second insulating layer has a height higher than that of the tunnel insulating layer.

11. The method of claim 7, wherein the first insulating layer and the second insulating layer are formed of material having the same etch rate.

12. The method of claim 7, wherein the first insulating layer and the second insulating layer are formed of an oxide layer.

13. The method of claim 7, wherein the shield layer is formed of a polysilicon layer.

14. The method of claim 7, wherein a width of the shield layer is smaller than ½ of the width of the second insulating layer.

15. The method of claim 7, comprising sequentially forming the first insulating layer and the shield layer.

16. A semiconductor memory device, comprising:
a semiconductor substrate in which a tunnel insulating layer, conductive layer, and a trench are formed;
an isolation layers formed within the trench; and
a shield layer formed at a center of the isolation layer.

17. The semiconductor memory device of claim 16, wherein the shield layer is formed between the isolation layers.

18. The method of claim 16, wherein the shield layer is formed of a polysilicon layer.
